(19) United States
(12) Patent Application Publication
(10) Pub. No.: US 2024/0203814 A1
(43) Pub. Date: Jun. 20, 2024

(54) SEMICONDUCTOR DEVICE

(71) Applicant: ROHM CO., LTD., Kyoto-shi (JP)

(72) Inventors: Kazuki YOSHIDA, Kyoto-shi (JP); Hajime KATAOKA, Kyoto-shi (JP)

(73) Assignee: ROHM CO., LTD., Kyoto-shi (JP)

(21) Appl. No.: 18/588,034

(22) Filed: Feb. 27, 2024

Related U.S. Application Data
(63) Continuation of application No. PCT/JP2022/030909, filed on Aug. 15, 2022.

(30) Foreign Application Priority Data
Sep. 3, 2021 (JP) 2021-144038

(51) Int. Cl. H01L 23/31; H01L 23/00; H01L 29/417

(52) U.S. Cl. CPC H01L 23/3171; H01L 24/40; H01L 29/41775; H01L 24/37; H01L 2224/37124; H01L 2224/37147; H01L 2224/40245; H01L 2924/13091

(57) ABSTRACT

A semiconductor device includes a semiconductor element and a conductive member. The semiconductor element includes a first wiring line connected to the conductive member, a second wiring line separated from the first wiring line and at least partially surrounding the first wiring line, and a passivation layer covering the first wiring line and the second wiring line. The passivation layer includes a first opening partially exposing the first wiring line as a connection region for the conductive member, a first slit located between the first opening and the second wiring line and partially exposing the first wiring line, and a second slit partially exposing the second wiring line.

### CROSS-REFERENCE TO RELATED APPLICATIONS

This application is a continuation of International Application No. PCT/JP2022/030909, filed Aug. 15, 2022, which claims priority to Japanese Patent Application No. 2021-144038, filed Sep. 3, 2021, the entire contents of each are incorporated herein by reference.

### BACKGROUND ART

### 1. Field

The present disclosure relates to a semiconductor device.

### 2. Description of Related Art

A semiconductor element such as a transistor includes a passivation layer (or passivation film) that protects the semiconductor element. Japanese Laid-Open Patent Publication No. 2020-136472 discloses a semiconductor device that includes a passivation film covering a surface electrode film of a transistor.

### BRIEF DESCRIPTION OF DRAWINGS

FIG. 1 is a schematic perspective view showing an exemplary semiconductor device according to an embodiment.

FIG. 2 is a schematic plan view of the semiconductor device with conductive members removed.

FIG. 3 is a schematic plan view showing an exemplary semiconductor element.

FIG. 4 is a schematic enlarged plan view showing a portion of the semiconductor element surrounded by double-dashed lines shown in FIG. 3.

FIG. 5 is a schematic cross-sectional view of the semiconductor element taken along line F5-F5 in FIG. 4.

FIG. 6 is a schematic cross-sectional view of the semiconductor element taken along line F6-F6 in FIG. 4.

FIG. 7 is an enlarged cross-sectional view of a portion shown in FIG. 6.

FIG. 8 is a schematic plan view showing an exemplary semiconductor element according to a modified example.

FIG. 9 is a schematic enlarged plan view showing a portion of the semiconductor element surrounded by double-dashed lines shown in FIG. 8.

FIG. 10 is a schematic cross-sectional view taken along line F10-F10 shown in FIG. 9.

### DETAILED DESCRIPTION

Embodiments of a semiconductor device according to the present disclosure will be described below with reference to the drawings. In the drawings, components may be partially enlarged for simplicity and clarity and are not necessarily drawn to scale. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

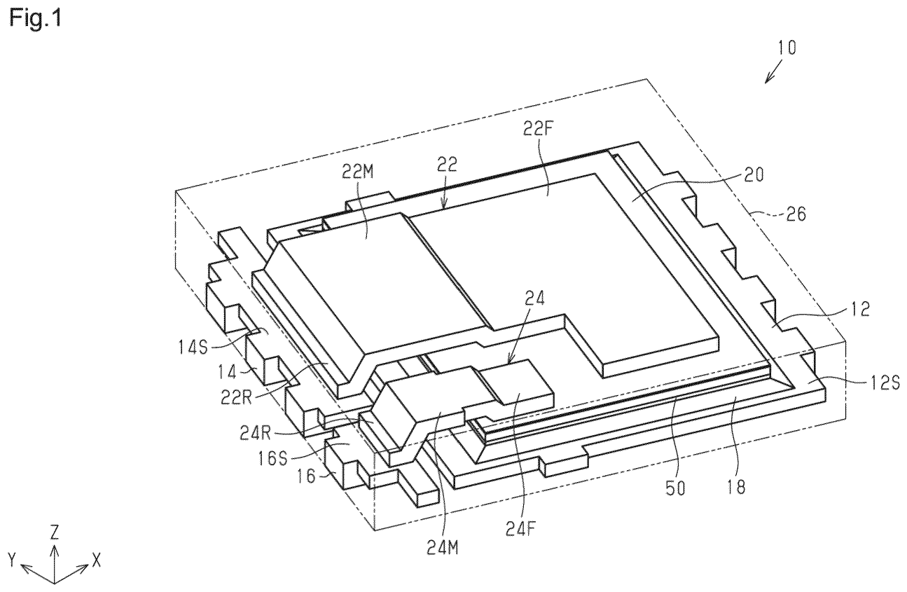

Unless otherwise specifically described, the term “plan view” used in the present disclosure refers to a view of an object (e.g., semiconductor device or component member) in a Z-direction when XYZ-axes (for example, refer to FIG. 1) are orthogonal to each other.

FIG. 1 is a schematic perspective view showing an exemplary semiconductor device 10 according to an embodiment. As shown in FIG. 1, the semiconductor device 10 is, for example, rectangular box-shaped. In an example, the semiconductor device 10 is rectangular in plan view. The size of the semiconductor device 10 is not particularly limited.

The semiconductor device 10 may have, for example, a structure that uses a lead frame. In the example shown in FIG. 1, the semiconductor device 10 includes a conductive plate 12, a first conductive terminal 14, a second conductive terminal 16, and a semiconductor element 20. The semiconductor element 20 is mounted on the conductive plate 12. In the example shown in FIG. 1, the semiconductor device 10 further includes a first conductive member 22, which connects the semiconductor element 20 to the first conductive terminal 14, and a second conductive member 24, which connects the semiconductor element 20 to the second conductive terminal 16. The semiconductor device 10 includes an encapsulation member 26 encapsulating the semiconductor element 20.

The semiconductor element 20 is bonded to the conductive plate 12 by a conductive bonding material 18. The conductive bonding material 18 may be, for example, solder or a conductive paste. An example of the solder may be lead (Pb)-free solder such as a tin (Sn)-silver (Ag)-copper (Cu)-based solder or may be lead-containing solder such as a Sn—Pb—Ag-based solder. An example of the conductive paste is Ag paste. The conductive plate 12, the first and second conductive terminals 14 and 16, and the first and second conductive members 22 and 24 are formed from, for example, a metal material such as Cu or aluminum (Al).

The semiconductor device 10 may be, for example, a package of a surface mount type. Although not shown in detail, the conductive plate 12 and the first and second conductive terminals 14 and 16 each include an external connection surface partially exposed from the encapsulation member 26 on the back surface of the semiconductor device 10. When the semiconductor device 10 is mounted on a mount substrate, which is not shown, the external connection surfaces of the conductive plate 12 and the first and second conductive terminals 14 and 16 are electrically connected to the mount substrate.

The conductive plate 12 and the first and second conductive terminals 14 and 16 may have any shape (any outer shape) and any thickness. The thickness refers to the dimension (length) in the Z-direction. In the example shown in FIG. 1, the conductive plate 12 and the first and second conductive terminals 14 and 16 are each flat. The first and second conductive terminals 14 and 16 are located adjacent to one side of the conductive plate 12 (side extending along the X-direction in FIG. 1).

The conductive plate 12 includes a bonding surface 12S that is bonded to the semiconductor element 20 by the conductive bonding material 18. The first conductive terminal 14 includes a bonding surface 14S that is bonded to the first conductive member 22 by a conductive bonding member (e.g., solder), which is not shown. Also, the second conductive terminal 16 includes a bonding surface 16S that is bonded to the second conductive member 24 by a conductive bonding member (e.g., solder), which is not shown.

The bonding surfaces 14S and 16S of the first and second conductive terminals 14 and 16 may be located at a position higher than (i.e., above) the bonding surface 12S of the conductive plate 12 in the Z-direction. In an example, the first and second conductive terminals 14 and 16 may be at least partially greater in thickness than the conductive plate 12. This structure allows for reduction in the length (connection distance) of the first conductive member 22, which connects the semiconductor element 20 and the first conductive terminal 14, and the length (connection distance) of the second conductive member 24, which connects the semiconductor element 20 and the second conductive terminal 16.

The first and second conductive members 22 and 24 may have any shape (any outer shape) and any thickness. In the example shown in FIG. 1, the first and second conductive members 22 and 24 are each bridge-shaped. A bridge-shaped conductive member such as the first and second conductive members 22 and 24 may be referred to as a clip. In an example, a clip formed from Cu may be referred to as a Cu clip.

The first conductive member 22 includes a first end portion 22F, a second end portion 22R, and an intermediate portion 22M located between the first end portion 22F and the second end portion 22R. The first end portion 22F is a flat plate. In the example shown in FIG. 1, the first end portion 22F is flat and has a generally L-shaped contour in plan view and is bonded to the semiconductor element 20 by a conductive bonding material (e.g., solder), which is not shown. The second end portion 22R is a flat plate. In the example shown in FIG. 1, the second end portion 22R is flat and rectangular in plan view and is bonded to the bonding surface 14S of the first conductive terminal 14 by a conductive bonding material, which is not shown. The intermediate portion 22M is bent in a stepped manner and bridges the first end portion 22F and the second end portion 22R.

In the same manner, the second conductive member 24 includes a first end portion 24F, a second end portion 24R, and an intermediate portion 24M located between the first end portion 24F and the second end portion 24R. The first end portion 24F is a flat plate. In the example shown in FIG. 1, the first end portion 24F is flat and rectangular in plan view and is bonded to the semiconductor element 20 by a conductive bonding material (e.g., solder), which is not shown. The second end portion 24R is a flat plate. In the example shown in FIG. 1, the second end portion 24R is flat and rectangular in plan view and is bonded to the bonding surface 16S of the second conductive terminal 16 by a conductive bonding material, which is not shown. In plan view, the second end portion 24R may be larger than the first end portion 24F. The intermediate portion 24M is bent in a stepped manner and bridges the first end portion 24F and the second end portion 24R.

The encapsulation member 26 may define the outer shape of the package of the semiconductor device 10. The encapsulation member 26 encapsulates the semiconductor element 20, the conductive plate 12, a part of the first conductive terminal 14, a part of the second conductive terminal 16, the first conductive member 22, and the second conductive member 24. The encapsulation member 26 is formed from, for example, an insulative resin material such as a black epoxy resin.

The semiconductor element 20 may be a switching element such as a transistor. In an example, the semiconductor element 20 may be a metal insulator semiconductor field effect transistor (MISFET). However, the semiconductor element 20 is not limited to the MISFET and may be, for example, an insulated gate bipolar transistor (IGBT) or another transistor type.

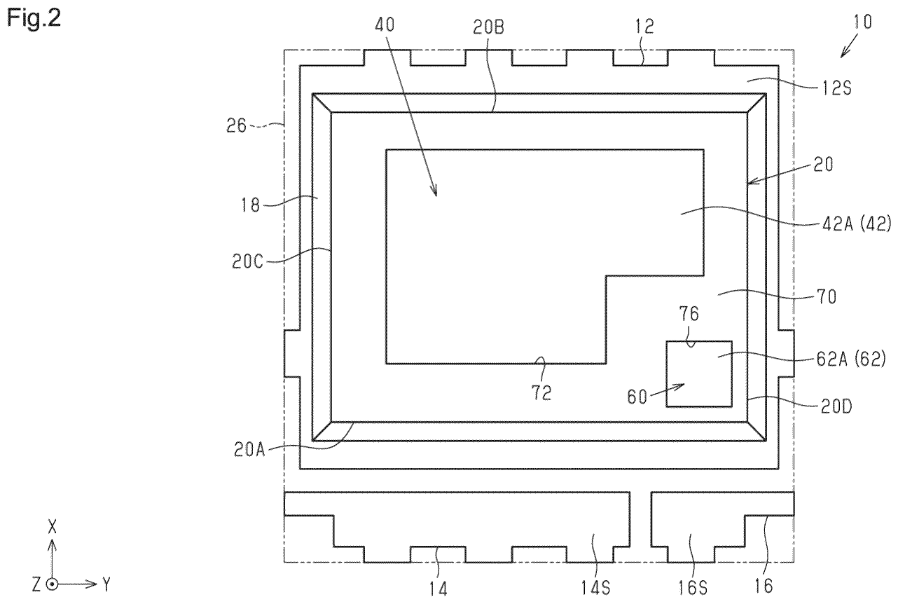

An example of the structure of the semiconductor element 20 will now be described with reference to FIGS. 2 to 7.

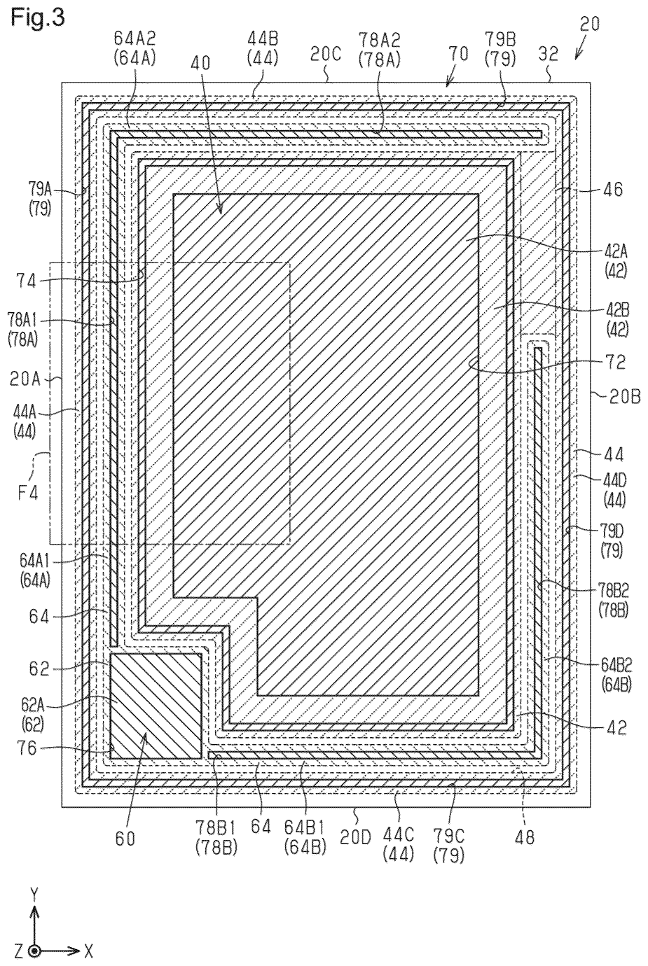

FIG. 2 is a schematic plan view of the semiconductor device 10 with the first and second conductive members 22 and 24 removed. FIG. 3 is a schematic plan view of the semiconductor element 20. For the sake of simplicity, FIG. 2 is a simplified plan view of the semiconductor element 20 shown in FIG. 3.

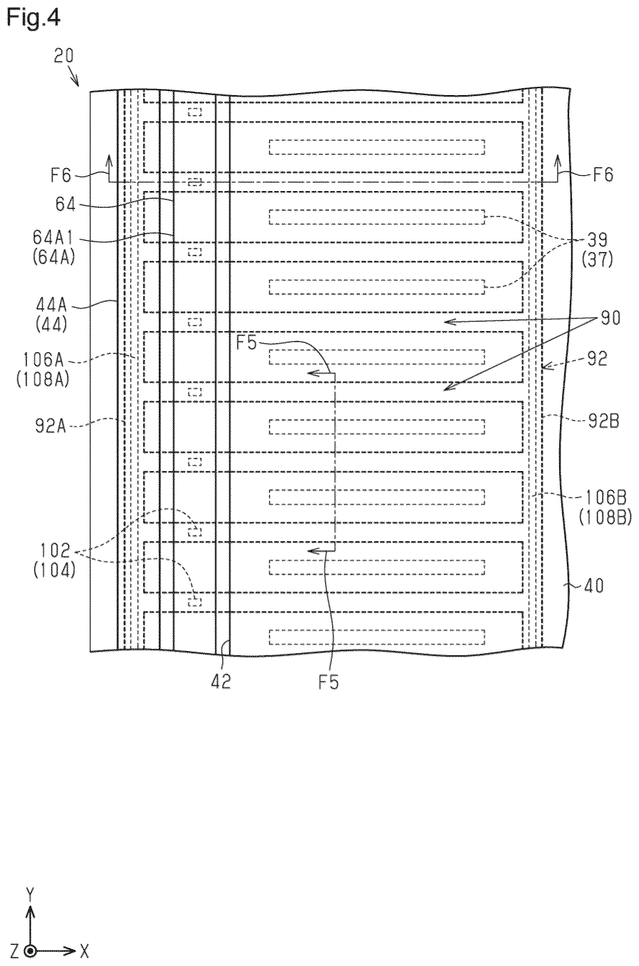

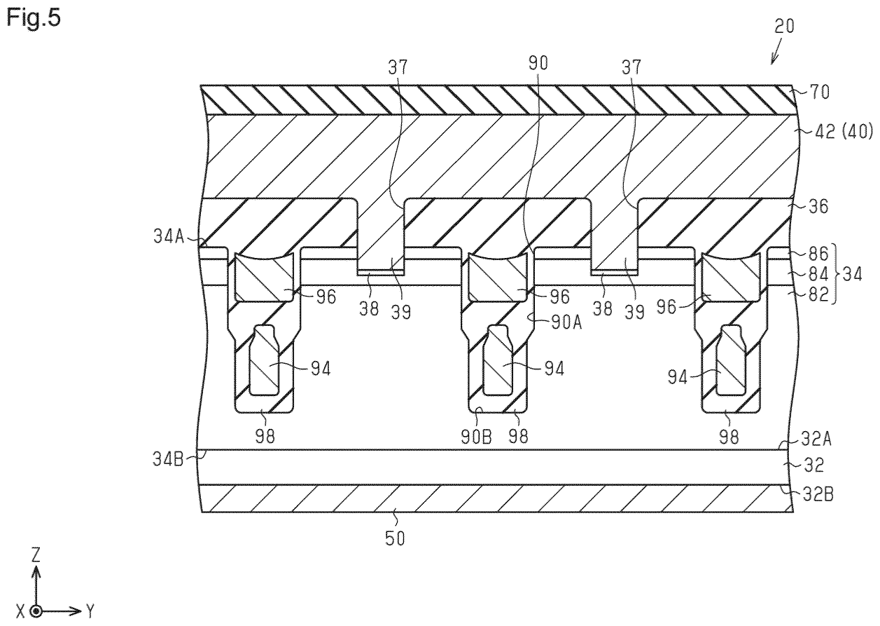

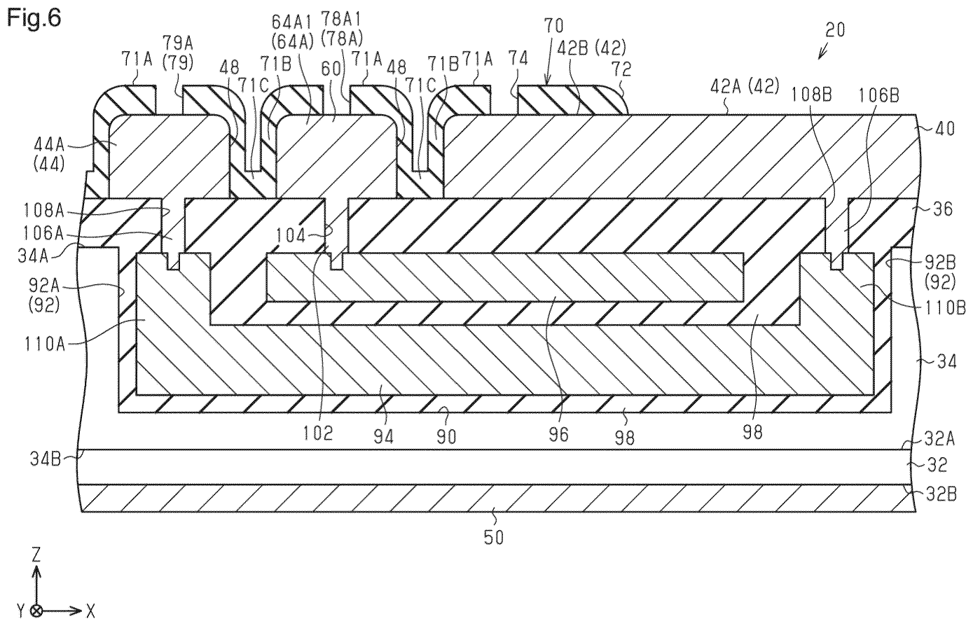

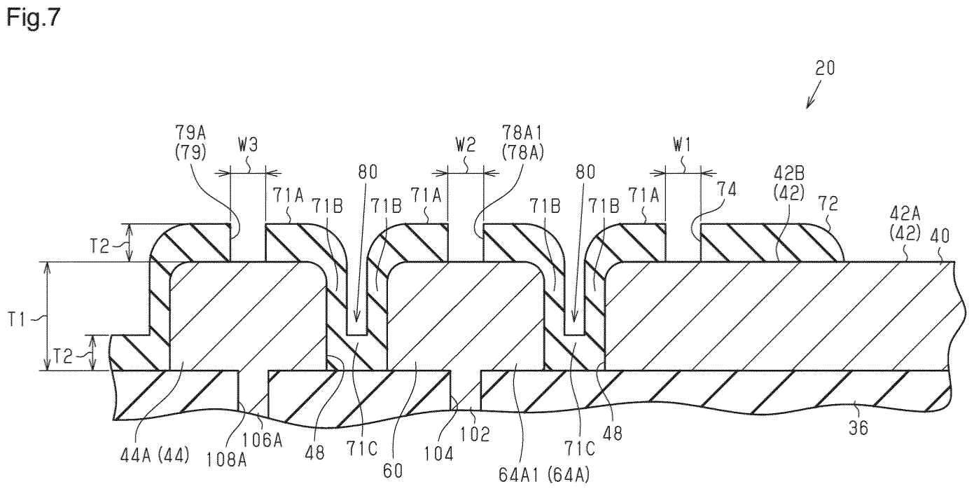

FIG. 4 is a schematic enlarged plan view of a portion of the semiconductor element 20 surrounded by the double-dashed lines F4 shown in FIG. 3. FIG. 5 is a schematic cross-sectional view taken along line F5-F5 shown in FIG. 4. FIG. 6 is a schematic cross-sectional view taken along line F6-F6 shown in FIG. 4. FIG. 7 is an enlarged cross-sectional view of a portion shown in FIG. 6.

In an example, the semiconductor element 20 includes a transistor having a split-gate structure. As shown in FIG. 3, the semiconductor element 20 is rectangular in plan view and includes first to fourth sides 20A, 20B, 20C, and 20D, which define the outer edges of the semiconductor element 20. The first and second sides 20A and 20B extend in the first direction (Y-direction) in plan view. The third and fourth sides 20C and 20D extend in the second direction (X-direction) orthogonal to the first direction in plan view. In the description hereafter, the Y-direction may be referred to as the first direction, and the X-direction may be referred to as the second direction.

In the example shown in FIG. 3, the first and second sides 20A and 20B have the same length. The third and fourth sides 20C and 20D have the same length. The third and fourth sides 20C and 20D have a smaller length than the first and second sides 20A and 20B. However, in another example, the third and fourth sides 20C and 20D may have the same length as the first and second sides 20A and 20B or have a greater length than the first and second sides 20A and 20B.

As shown in FIGS. 5 and 6, the semiconductor element 20 includes a semiconductor substrate 32, a semiconductor layer 34, and an insulation layer 36. The semiconductor substrate 32 is, for example, a silicon (Si) substrate. The semiconductor substrate 32 is rectangular in plan view and includes four sides corresponding to the first to fourth sides 20A, 20B, 20C, and 20D (refer to FIG. 3). The semiconductor substrate 32 includes a first surface 32A (upper surface in FIGS. 5 and 6) and a second surface 32B (lower surface shown in FIGS. 5 and 6) opposite to the first surface 32A.

The semiconductor layer 34 is arranged on the first surface 32A of the semiconductor substrate 32. The semiconductor layer 34 includes a first surface 34A (upper surface in FIGS. 5 and 6) and a second surface 34B (lower surface shown in FIGS. 5 and 6) opposite to the first surface 34A. In the example shown in FIGS. 5 and 6, the second surface 34B of the semiconductor layer 34 is in contact with the first surface 32A of the semiconductor substrate 32. The second surface 34B of the semiconductor layer 34 covers, for example, the entirety of the first surface 32A of the semiconductor substrate 32. The semiconductor layer 34 may be formed of, for example, a Si epitaxial layer.

The insulation layer 36 is arranged on the first surface 34A of the semiconductor layer 34. In the example shown in FIGS. 5 and 6, the insulation layer 36 is a single layer; however, it may include multiple layers. In an example, the insulation layer 36 may include at least one of a silicon oxide (SiO₂) layer and a silicon nitride (SiN) layer. Alternatively, in an example, the insulation layer 36 may have a two-layer structure including an undoped silicate glass (USG) layer that includes no impurity and a boron-phosphorus silicate glass (BPSG) layer covering the USG layer and including boron and phosphorus as an impurity. The insulation layer 36 may also be referred to as an inter-layer insulation film (inter-layer dielectric: ILD).

As shown in FIGS. 3, 5, and 6, the semiconductor element 20 includes a source electrode layer 40, a drain electrode layer 50, a gate electrode layer 60, and a passivation layer 70. The source electrode layer 40 and the gate electrode layer 60 are arranged on the insulation layer 36. The drain electrode layer 50 is arranged on the second surface 32B of the semiconductor substrate 32. The drain electrode layer 50 may cover the entirety of the second surface 32B of the semiconductor substrate 32.

The passivation layer 70 covers the source electrode layer 40 and the gate electrode layer 60. In the example shown in FIG. 3, the passivation layer 70 is identical in shape to the semiconductor substrate 32 (the semiconductor element 20) in plan view. The passivation layer 70 partially exposes the source electrode layer 40 and partially exposes the gate electrode layer 60. In FIG. 3, to facilitate understanding, the source electrode layer 40 is indicated by right-upward diagonal hatching lines. The gate electrode layer 60 is indicated by left-upward diagonal hatching lines. Portions of the source electrode layer 40 and the gate electrode layer 60 exposed from the passivation layer 70 are indicated by solid lines. Portions of the source electrode layer 40 and the gate electrode layer 60 covered by the passivation layer 70 are indicated by broken lines.

As shown in FIG. 3, the source electrode layer 40 may include a source electrode 42, a source finger 44, and a connector 46. The source finger 44 is connected to the source electrode 42 by the connector 46. The source electrode 42 and the source finger 44 are formed continuously and integrally with the connector 46.

The source electrode 42 may cover an active region of the semiconductor element 20. In the example shown in FIG. 3, the source electrode 42 is, for example, generally L-shaped in plan view. The active region is a region of a semiconductor element where the transistor structure contributing to the operation of a transistor (semiconductor element 20) is mainly arranged. However, the active region does not have to be entirely the transistor structure. In an example, a structure differing from the transistor structure may be partially arranged in the active region. In another example, the transistor structure may be partially arranged outside the active region.

The source electrode 42 includes a source pad 42A and a source pad peripheral portion 42B arranged on the periphery of the source pad 42A and forming a peripheral portion of the source electrode 42. The source pad peripheral portion 42B is formed continuously and integrally with the source pad 42A. The source electrode 42 corresponds to a first wiring line. The source pad 42A corresponds to a connection region.

The source pad 42A is, for example, generally L-shaped in plan view and is slightly smaller than the source electrode 42. The passivation layer 70 includes a source pad opening 72 exposing the source pad 42A of the source electrode 42. The source pad opening 72 corresponds to a first opening.

The source pad 42A exposed from the source pad opening 72 is bonded to the first end portion 22F (refer to FIG. 1) of the first conductive member 22, which is described above. Hence, the source pad 42A (the source pad opening 72) is to the same size as or slightly larger than the first end portion 22F of the first conductive member 22 in plan view.

The passivation layer 70 includes a source electrode exposure slit 74 partially exposing the source pad peripheral portion 42B. The source electrode exposure slit 74 corresponds to a first slit.

The source electrode exposure slit 74 is annularly formed in a portion of the passivation layer 70 overlapping the source pad peripheral portion 42B in plan view. In the example shown in FIG. 3, the source electrode exposure slit 74 is closed-annular-shaped. Thus, the source electrode exposure slit 74 is formed along the entire outer circumference of the source pad peripheral portion 42B (peripheral portion of the source electrode 42). In other words, the source electrode exposure slit 74 partially exposes the source pad peripheral portion 42B along the entire outer circumference of the source pad peripheral portion 42B.

The term “annular” as used in the present disclosure is not limited to a structure that forms a continuous shape with no ends, that is, a loop, but may refer to, for example, a substantially-loop-shaped structure with a slit (gap) such as a C-shaped structure. Therefore, the explicit term “closed annular” refers to any structure that forms a continuous shape with no ends, or a loop. The explicit term “open annular” refers to a generally-loop-shaped structure with a slit. Such “annular” shapes include an ellipse and any shape including corners including a right-angled corner or a round corner.

The gate electrode layer 60 is separated from the source electrode 42 and at least partially surrounds the source electrode 42. The gate electrode layer 60 corresponds to a second wiring line. In the example shown in FIG. 3, a separation region 48 is formed between the gate electrode layer 60 and the source electrode layer 40. The separation region 48 may have an annular shape (closed annular shape) surrounding the entire perimeter of the gate electrode layer 60 in plan view. The separation region 48 is free of an electrode layer and at least partially receives the passivation layer 70 (refer to FIG. 6). Thus, the gate electrode layer 60 and the source electrode layer 40 are insulated from each other by the passivation layer 70. The separation distance between the gate electrode layer 60 and the source electrode layer 40 may be determined taking into consideration, for example, breakdown voltage.

The gate electrode layer 60 may include a gate electrode 62 and a gate finger 64. In the example shown in FIG. 3, the gate electrode 62 is rectangular in plan view. The gate finger 64 is separated from the source electrode 42 and extends along the source electrode 42. The gate finger 64 extends from the gate electrode 62 so as to annularly surround the source electrode 42. In the example shown in FIG. 3, the gate finger 64 includes first and second gate finger portions 64A and 64B extending from the gate electrode 62. The first and second gate finger portions 64A and 64B are formed continuously and integrally with the gate electrode 62.

The gate electrode 62 includes a gate pad 62A. In the example shown in FIG. 3, the gate pad 62A is rectangular in plan view. The gate pad 62A is slightly smaller than the gate electrode 62. The passivation layer 70 includes a gate pad opening 76 exposing the gate pad 62A of the gate electrode 62.

The gate pad 62A exposed from the gate pad opening 76 is bonded to the first end portion 24F (refer to FIG. 1) of the second conductive member 24, which is described above. Thus, the gate pad 62A (the gate pad opening 76) is the same size as or slightly larger than the first end portion 24F of the second conductive member 24 in plan view.

The gate electrode 62 and the first and second gate finger portions 64A and 64B surround the source electrode 42 except a region of the connector 46 of the source electrode layer 40. Thus, the gate electrode layer 60 is open-annular-shaped.

In the example shown in FIG. 3, the first gate finger portion 64A includes a first part 64A1 linearly extending from the gate electrode 62 along the first side 20A (left side shown in FIG. 3) and a second part 64A2 linearly extending from the first part 64A1 along the third side 20C (upper side shown in FIG. 3). Thus, the first gate finger portion 64A is L-shaped in plan view.

The second gate finger portion 64B includes a first part 64B1 linearly extending from the gate electrode 62 along the fourth side 20D (lower side shown in FIG. 3) and a second part 64B2 linearly extending from the first part 64B1 along the second side 20B (right side shown in FIG. 3). Thus, the second gate finger portion 64B is L-shaped in plan view.

The distal end of the second part 64A2 of the first gate finger portion 64A is opposed to the distal end of the second part 64B2 of the second gate finger portion 64B with an open region corresponding to the connector 46 of the source electrode layer 40. Therefore, while the first gate finger portion 64A, the gate electrode 62, and the second gate finger portion 64B are annular and continuous with each other, the entirety of the gate electrode layer 60 is open-annular-shaped.

The passivation layer 70 includes a first gate finger exposure slit 78A partially exposing the first gate finger portion 64A and a second gate finger exposure slit 78B partially exposing the second gate finger portion 64B. The first and second gate finger exposure slits 78A and 78B each correspond to a second slit.

The first gate finger exposure slit 78A may be L-shaped and be formed in a portion of the passivation layer 70 overlapping the first gate finger portion 64A in plan view. In the example shown in FIG. 3, the first gate finger exposure slit 78A includes a first slit part 78A1 linearly extending on the first part 64A1 of the first gate finger portion 64A and a second slit part 78A2 linearly extending on the second part 64A2 of the first gate finger portion 64A.

In an example, the first slit part 78A1 exposes a central portion of the first part 64A1 along the entire length of the first part 64A1 of the first gate finger portion 64A. In the same manner, the second slit part 78A2 exposes a central portion of the second part 64A2 along the entire length of the second part 64A2 of the first gate finger portion 64A. The first slit part 78A1 is continuous with the second slit part 78A2. The portion connecting the first slit part 78A1 and the second slit part 78A2 is located on the corner of the first gate finger portion 64A. As described above, the first slit part 78A1 and the second slit part 78A2 form the first gate finger exposure slit 78A that is L-shaped in the same manner as the first gate finger portion 64A.

The term “entire length” used in the present disclosure includes not only a case where the length of a member is exactly the same as the length from one end to the other end of the member but also a case where the length of the member is slightly shorter (that is, substantially the same as) than the length from one end to the other end.

The second gate finger exposure slit 78B may be L-shaped and be formed in a portion of the passivation layer 70 overlapping the second gate finger portion 64B in plan view. In the example shown in FIG. 3, the second gate finger exposure slit 78B includes the first slit part 78B1 linearly extending on the first part 64B1 of the second gate finger portion 64B and the second slit part 78B2 linearly extending on the second part 64B2 of the second gate finger portion 64B.

In an example, the first slit part 78B1 exposes a central portion of the first part 64B1 along the entire length of the first part 64B1 of the second gate finger portion 64B. In the same manner, the second slit part 78B2 exposes a central portion of the second part 64B2 along the entire length of the second part 64B2 of the second gate finger portion 64B. The first slit part 78B1 is continuous with the second slit part 78B2. The portion connecting the first slit part 78B1 and the second slit part 78B2 is located on the corner of the second gate finger portion 64B. As described above, the first slit part 78B1 and the second slit part 78B2 form the second gate finger exposure slit 78B that is L-shaped in the same manner as the second gate finger portion 64B.

The source finger 44 is separated from the gate electrode layer 60 by the separation region 48 and at least partially surrounds the gate electrode layer 60. The source finger 44 corresponds to a third wiring line. In an example, the source finger 44 has a closed annular shape surrounding the periphery of the gate electrode layer 60. The source finger 44 is connected to the connector 46 of the source electrode layer 40.

In the example shown in FIG. 3, the source finger 44 includes four parts, namely, first to fourth parts 44A, 44B, 44C, and 44D, having a closed annular shape. The first part 44A of the source finger 44 linearly extends along the first side 20A (left side shown in FIG. 3), that is, along the gate electrode 62 and the first part 64A1 of the first gate finger portion 64A. The second part 44B of the source finger 44 linearly extends along the third side 20C (upper side shown in FIG. 3), that is, along the second part 64A2 of the first gate finger portion 64A. The third part 44C of the source finger 44 linearly extends along the fourth side 20D (lower side shown in FIG. 3), that is, along the first part 64B1 of the second gate finger portion 64B. The fourth part 44D of the source finger 44 linearly extends along the second side 20B (right side shown in FIG. 3), that is, along the second part 64B2 of the second gate finger portion 64B and the connector 46 of the source electrode layer 40.

The fourth part 44D of the source finger 44 is formed continuously and integrally with the connector 46 of the source electrode layer 40. The first to fourth parts 44A, 44B, 44C, and 44D of the source finger 44 are formed continuously and integrally with each other. The source finger 44 is closed-annular-shaped by the first to fourth parts 44A, 44B, 44C, and 44D.

The passivation layer 70 includes a source finger exposure slit 79 partially exposing the source finger 44. The source finger exposure slit 79 corresponds to a third slip.

The source finger exposure slit 79 may be annularly formed in a portion of the passivation layer 70 overlapping the source finger 44 in plan view. In the example shown in FIG. 3, the source finger exposure slit 79 is closed-annular-shaped. Thus, the source finger exposure slit 79 is formed along the entire length of the source finger 44. In other words, the source finger exposure slit 79 partially exposes the source finger 44 along the entire outer circumference of the source finger 44.

In the example shown in FIG. 3, the source finger exposure slit 79 includes four slit parts, namely, first to fourth slit parts 79A, 79B, 79C, and 79D, having a closed annular shape. The first slit part 79A linearly extends on the first part 44A of the source finger 44. In the same manner, the second to fourth slit parts 79B, 79C, and 79D linearly extend on the second to fourth parts 44B, 44C, and 44D of the source finger 44, respectively.

In an example, the first slit part 79A exposes a central portion of the first part 44A along the entire length of the first part 44A of the source finger 44. In the same manner, the second to fourth slit parts 79B, 79C, and 79D expose a central portion of the second to fourth parts 44B, 44C, and 44D along the entire length of the second to fourth parts 44B, 44C, and 44D of the source finger 44, respectively.

The first to fourth slit parts 79A, 79B, 79C, and 79D of the source finger exposure slit 79 are continuous with each other. The portion connecting the first and second slit parts 79A and 79B, the portion connecting the first and third slit parts 79A and 79C, the portion connecting the second and fourth slit parts 79B and 79D, and the portion connecting the third and fourth slit parts 79C and 79D are located on the four corners of the source finger 44. Thus, the source finger exposure slit 79 is closed-annular-shaped by the first to fourth slit parts 79A, 79B, 79C, and 79D in the same manner as the source finger 44.

An example of the transistor structure will now be described in detail with reference to FIGS. 4 to 6.

In FIG. 5, the semiconductor substrate 32 including the drain electrode layer 50 is used as a drain region of a transistor (MISFET). The semiconductor layer 34 includes a drift region 82 formed on the semiconductor substrate 32 (drain region), a body region 84 formed on the drift region 82, and a source region 86 formed on the body region 84.

In an example, the semiconductor substrate 32, which corresponds to the drain region, is an n-type region including a n-type impurity. The drift region 82 is an n-type region including an n-type impurity at a lower concentration than the semiconductor substrate 32 (drain region). The body region 84 is a p-type region including a p-type impurity. The source region 86 is an n-type region including an n-type impurity at a higher concentration than the drift region 82. Examples of the n-type impurity include phosphorus (P) and arsenic (As). Examples of the p-type impurity include boron (B) and aluminum (Al).

As shown in FIGS. 4 and 5, the semiconductor element 20 may include gate trenches 90 formed in the first surface 34A of the semiconductor layer 34. At least some of the gate trenches 90 may be equidistantly arranged parallel to each other. In the example shown in FIG. 4, the gate trenches 90 are equidistantly arranged parallel to each other in the first direction (Y-direction) along the first part 64A1 of the first gate finger portion 64A and the first part 44A of the source finger 44. The gate trenches 90 extend from the source electrode 42 to the first part 44A of the source finger 44 in the second direction (the X-direction) and intersect with the first part 64A1 of the first gate finger portion 64A in plan view.

FIG. 4 shows the portion of the semiconductor element 20 surrounded by the double-dashed lines F4 shown in FIG. 3. In the same manner as the gate trenches 90 shown in FIG. 4, a number of gate trenches is formed in the semiconductor layer 34 at other portions of the semiconductor element 20.

In an example, in FIG. 3, one or more gate trenches may be equidistantly arranged parallel to each other in the second direction (the X-direction) along the second part 64A2 of the first gate finger portion 64A and the second part 44B of the source finger 44. These gate trenches extend from the source electrode 42 to the second part 44B of the source finger 44 in the first direction (Y-direction) and intersect with the second part 64A2 of the first gate finger portion 64A in plan view.

Also, one or more gate trenches may be equidistantly arranged parallel to each other in the second direction (the X-direction) along the first part 64B1 of the second gate finger portion 64B and the third part 44C of the source finger 44. These gate trenches extend from the source electrode 42 to the third part 44C of the source finger 44 in the first direction (Y-direction) and intersect with the first part 64B1 of the second gate finger portion 64B in plan view.

One or more gate trenches may be equidistantly arranged parallel to each other in the first direction (Y-direction) along the second part 64B2 of the second gate finger portion 64B and the fourth part 44D of the source finger 44. These gate trenches extend from the source electrode 42 to the fourth part 44D of the source finger 44 in the second direction (the X-direction) and intersect with the second part 64B2 of the second gate finger portion 64B in plan view.

The following description mainly focuses on the structure of the portion of the semiconductor element 20 shown in FIG. 4. However, the structure is the same in other portions, and the following description may apply to the structure of other portions.

As shown in FIGS. 4 and 6, the semiconductor element 20 may include a peripheral trench 92 formed in the first surface 34A of the semiconductor layer 34. The peripheral trench 92 and the gate trenches 90 communicate. In the example shown in FIG. 4, the peripheral trench 92 includes a first peripheral trench portion 92A formed in a position overlapping the source finger 44 and extending in the first direction (Y-direction) in plan view. The peripheral trench 92 includes a second peripheral trench portion 92B formed in a position overlapping the source electrode 42 and extending in the first direction (Y-direction). As shown in FIG. 6, the first and second peripheral trench portions 92A and 92B communicate with the gate trench 90. The peripheral trench 92 may extend around the gate trenches 90 in plan view.

As shown in FIG. 5, a field plate electrode 94, an embedded gate electrode 96, and a trench insulation layer 98 are arranged in each of the gate trenches 90. A single gate trench 90 and its related structures will be described below. However, the following description may apply to each of the gate trenches 90 and its related structure.

As shown in FIGS. 5 and 6, the field plate electrode 94 and the embedded gate electrode 96 are separated from each other by the trench insulation layer 98. The trench insulation layer 98 covers side walls 90A and a bottom wall 90B of the gate trench 90 and fills the gate trench 90. The trench insulation layer 98 also fills the peripheral trench 92. The embedded gate electrode 96 is located above the field plate electrode 94 in the gate trench 90. The structure in which two separate electrodes (field plate electrode 94 and embedded gate electrode 96) are embedded in the gate trench 90 may be referred to as a split-gate structure.

The semiconductor element 20, which includes a number of gate trenches 90, may include the same number of field plate electrodes 94 as the gate trenches 90 and the same number of embedded gate electrodes 96 as the gate trenches 90. The field plate electrodes 94 and the embedded gate electrodes 96 may be formed from, for example, conductive polysilicon. The trench insulation layers 98 may be formed from, for example, SiO₂.

The field plate electrodes 94 are surrounded by the trench insulation layers 98. Application of the source voltage to the field plate electrodes 94 will reduce concentration of electric field in the gate trenches 90 and improve the breakdown voltage of the semiconductor element 20. Thus, the field plate electrodes 94 may be controlled to have the same potential as the source region 86.

The trench insulation layer 98 is located between the embedded gate electrode 96 and the semiconductor layer 34. In other words, the embedded gate electrode 96 and the semiconductor layer 34 are separated from each other by the trench insulation layer 98 (in the Y-direction in FIG. 5). When a predetermined voltage is applied to the embedded gate electrode 96, a channel is formed in the body region 84 (p-type region). The channel controls the flow of electrons between the source region 86 (n-type region) and the drift region 82 (n-type region) (in the Z-direction in FIG. 5).

The insulation layer 36, which is formed on the first surface 34A of the semiconductor layer 34, covers the embedded gate electrodes 96 and the trench insulation layers 98 embedded in the gate trenches 90. Contact trenches 37 are formed in the insulation layer 36. The contact trenches 37 extend through the insulation layer 36 and the source region 86 to the body region 84. A contact region 38 is formed on the bottom of each contact trench 37. In an example, the contact region 38 is a p-type region including a p-type impurity at a lower concentration than the body region 84.

As shown in FIGS. 4 and 5, each contact trench 37 is filled with a source contact 39. The contact trench 37 and the source contact 39, which fills the contact trench 37, may extend parallel to the gate trench 90 (in the X-direction in FIG. 4) in plan view. Each gate trench 90 is located between two of the source contacts 39 adjacent to each other in plan view. The source contacts 39 are connected to the source electrode 42 (the source electrode layer 40), which is formed on the insulation layer 36. Thus, the contact regions 38 are electrically connected to the source electrode 42 via the source contacts 39.

As shown in FIG. 6, the embedded gate electrode 96 is connected to a gate contact 102, which is formed in the insulation layer 36, and is connected to the first gate finger portion 64A (the gate electrode layer 60). The gate contact 102 fills a contact via 104 that extends through the insulation layer 36. As shown in FIG. 4, the contact via 104 and the gate contact 102, which fills the contact via 104, are arranged to overlap the first gate finger portion 64A (the first part 64A1 in the example shown in FIG. 4) in plan view. More specifically, the embedded gate electrode 96, which is arranged in the gate trench 90, extends (in the X-direction in FIG. 4) and intersects the first gate finger portion 64A in plan view. At the intersection, the embedded gate electrode 96 is electrically connected to the first gate finger portion 64A by the gate contact 102 (refer to FIG. 6).

As shown in FIG. 6, the field plate electrode 94 is connected to the source finger 44 (the source electrode layer 40) by a first field plate contact 106A, which is formed in the insulation layer 36, and a first conductive member 110A, which is arranged immediately below the first field plate contact 106A. The field plate electrode 94 may be connected to the source electrode 42 (the source electrode layer 40) by a second field plate contact 106B, which is formed in the insulation layer 36, and a second conductive member 110B, which is arranged immediately below the second field plate contact 106B. The first and second field plate contacts 106A and 106B fill first and second contact trenches 108A and 108B, which extend through the insulation layer 36. In an example, the first conductive member 110A is arranged in the first peripheral trench portion 92A. The second conductive member 110B is arranged in the second peripheral trench portion 92B. In an example, the first and second conductive members 110A and 110B may be formed from conductive polysilicon.

As shown in FIG. 4, the first contact trench 108A and the first field plate contact 106A, which fills the first contact trench 108A, are arranged to overlap the source finger 44 (the first part 44A in the example shown in FIG. 4) and the first peripheral trench portion 92A. The first contact trench 108A and the first field plate contact 106A extend along the first peripheral trench portion 92A (in the Y-direction shown in FIG. 4). Although not described in detail, for example, the first conductive member 110A extends in the first peripheral trench portion 92A along the first field plate contact 106A (in the Y-direction shown in FIG. 4). The first conductive member 110A is connected to the field plate electrodes 94, which are arranged in the gate trenches 90 communicating with the first peripheral trench portion 92A. Thus, the field plate electrodes 94 are electrically connected to the source finger 44 (the source electrode layer 40) by the first conductive member 110A and the first field plate contact 106A (refer to FIG. 6).

The second contact trench 108B and the second field plate contact 106B, which fills the second contact trench 108B, are arranged to overlap the source electrode 42 and the second peripheral trench portion 92B in plan view. The second contact trench 108B and the second field plate contact 106B extend along the second peripheral trench portion 92B (in the Y-direction in FIG. 4). Although not shown in detail, for example, the second conductive member 110B extends in the second peripheral trench portion 92B along the second field plate contact 106B (in the Y-direction shown in FIG. 4). The second conductive member 110B is connected to the field plate electrodes 94, which are arranged in the gate trenches 90 communicating with the second peripheral trench portion 92B. Thus, the field plate electrodes 94 are electrically connected to the source electrode 42 (the source electrode layer 40) by the second conductive member 110B and the second field plate contact 106B (refer to FIG. 6).

As described above, each of the field plate electrodes 94 has one end connected to the source finger 44 (the source electrode layer 40) and another end connected to the source electrode 42 (the source electrode layer 40). Thus, the two ends of the field plate electrode 94 are connected to the source electrode layer 40. With this structure, the resistance of the field plate electrode 94 is decreased as compared to a structure in which, for example, only one of the two ends of the field plate electrode 94 is connected to the source electrode layer 40 (e.g., a structure in which the source electrode layer 40 does not include the source finger 44). In addition, during operation of a transistor, an increase in the electrical potential of the field plate electrode 94 is limited so that the operation of the transistor is stabilized.

As shown in FIG. 6, the passivation layer 70 covers the source electrode layer 40 and the gate electrode layer 60. As described above, the annular (closed annular in the example shown in FIG. 3) separation region 48 is formed between the source electrode layer 40 and the gate electrode layer 60. The passivation layer 70 is partially arranged in the separation region 48 and thus is formed on the insulation layer 36. Thus, the passivation layer 70 covers a first surface (upper surface shown in FIG. 7) and a second surface (side surface shown in FIG. 7) of the source electrode layer 40. The passivation layer 70 covers a first surface (upper surface shown in FIG. 7) and a second surface (side surface shown in FIG. 7) of the gate electrode layer 60.

The first surface of the source electrode layer 40 defines a surface of the source electrode layer 40 exposed from the source pad opening 72 of the passivation layer 70, the source electrode exposure slit 74, and the source finger exposure slit 79 (refer to FIG. 3). The second surface of the source electrode layer 40 defines a surface of the source electrode layer 40 that is continuous with the first surface of the source electrode layer 40 and forms the separation region 48. To facilitate understanding, the first surface of the source electrode layer 40 is referred to as the upper surface of the source electrode layer 40. The second surface of the source electrode layer 40 is referred to as the side surface of the source electrode layer 40.

In the same manner, the first surface of the gate electrode layer 60 defines a surface of the gate electrode layer 60 exposed from the gate pad opening 76 (refer to FIG. 3) of the passivation layer 70, the first gate finger exposure slit 78A, and the second gate finger exposure slit 78B (refer to FIG. 3). The second surface of the gate electrode layer 60 defines a surface of the gate electrode layer 60 that is continuous with the first surface of the gate electrode layer 60 and forms the separation region 48. To facilitate understanding, the first surface of the gate electrode layer 60 is referred to as the upper surface of the gate electrode layer 60. The second surface of the gate electrode layer 60 is referred to as the side surface of the gate electrode layer 60.

As shown in FIG. 7, the source electrode layer 40 and the gate electrode layer 60 are formed to have a thickness T1. That is, the source electrode layer 40 and the gate electrode layer 60 may have the same thickness. Alternatively, the source electrode layer 40 and the gate electrode layer 60 may have different thicknesses. The passivation layer 70 has a thickness T2 that is less than the thickness T1 of the source electrode layer 40 and the thickness T1 of the gate electrode layer 60. The thickness T2 may be, for example, less than or equal to ½ of the thickness T1. In an example, the thickness T1 of the source electrode layer 40 and the gate electrode layer 60 is approximately 4.2 μm. The thickness T2 of the passivation layer 70 is approximately 1.6 μm.

The passivation layer 70 includes a first covering part 71A and a second covering part 71B. The first covering part 71A covers the upper surface of the source electrode layer 40 and the upper surface of the gate electrode layer 60. The second covering part 71B is located in the separation region 48 and covers the side surface of the source electrode layer 40 and the side surface of the gate electrode layer 60. The passivation layer 70 includes a third covering part 71C located on the insulation layer 36 in the separation region 48.

The separation region 48 forms steps between the source pad peripheral portion 42B (i.e., the source electrode 42) and the first gate finger portion 64A and between the source finger 44 and the first gate finger portion 64A. Although not shown, steps are also formed between the source pad peripheral portion 42B and the second gate finger portion 64B and between the source pad peripheral portion 42B and the gate electrode 62. Also, although not shown, steps are formed between the source finger 44 and the second gate finger portion 64B and between the source finger 44 and the gate electrode 62.

Thus, the passivation layer 70 is formed in a stepped manner at the separation region 48. More specifically, the passivation layer 70 includes steps formed by the first covering part 71A, which covers the upper surface of the source electrode layer 40 and the upper surface of the gate electrode layer 60, and the second covering part 71B, which is located in the separation region 48 and covers the side surface of the source electrode layer 40 and the side surface of the gate electrode layer 60. The third covering part 71C connects the second covering part 71B, which covers the side surface of the source electrode layer 40, and the second covering part 71B, which covers the side surface of the gate electrode layer 60. The first covering part 71A may have the same thickness (i.e., the thickness T2) as the third covering part 71C. In the separation region 48, the third covering part 71C may be greater in thickness than the first covering part 71A.

A gap 80 may be present between the second covering part 71B that covers the side surface of the source electrode layer 40 and the second covering part 71B that covers the side surface of the gate electrode layer 60. In FIG. 7, the size (width) of the gap 80 is exaggerated. The gap 80 may have a size such that the gap 80 is barely present in the separation region 48. Alternatively, the gap 80 may be substantially embedded in the separation region 48.

The source pad opening 72, the source electrode exposure slit 74, and the source finger exposure slit 79 of the passivation layer 70 are formed in the first covering part 71A. The gate pad opening 76 (refer to FIG. 3), the first gate finger exposure slit 78A, and the second gate finger exposure slit 78B (refer to FIG. 3) of the passivation layer 70 are also formed in the first covering part 71A.

The source electrode exposure slit 74 has a slit width W1. The first and second gate finger exposure slits 78A and 78B have a slit width W2. The source finger exposure slit 79 has a slit width W3. The slit widths W1, W2, and W3 may have the same value.

Alternatively, the slit widths W1, W2, and W3 may have different values. In an example, the slit width W2 of the first and second gate finger exposure slits 78A and 78B may have a smaller value (or a larger value) than the slit width W1 of the source electrode exposure slit 74. Alternatively, the slit width W3 of the source finger exposure slit 79 may have a smaller value (or a larger value) than the slit width W1 of the source electrode exposure slit 74.

As described above with reference to the examples shown in FIGS. 3 to 6, the gate trenches 90 extend from the source electrode 42 to the source finger 44 in one of the first direction (Y-direction) and the second direction (the X-direction) and intersect with one of the first gate finger portion 64A and the second gate finger portion 64B. Each embedded gate electrode 96 extends in the gate trench 90 from the source electrode 42 to the first gate finger portion 64A (refer to, for example, FIG. 6) or the second gate finger portion 64B. Each field plate electrode 94 extends in the gate trench 90 from a position (the first conductive member 110A) overlapping the source finger 44 in plan view to a position (the second conductive member 110B) overlapping the source electrode 42 in plan view.

In this structure, in addition to the region immediately below the source electrode 42, a region immediately below the gate finger 64 (the first and second gate finger portions 64A and 64B) and a region immediately below the source finger 44 are also considered as a substantive active region (semiconductor element region) contributing to operation of a transistor (the semiconductor element 20). The source electrode exposure slit 74, the first gate finger exposure slit 78A, the second gate finger exposure slit 78B (refer to FIG. 3), and the source finger exposure slit 79 are arranged to overlap the active region (semiconductor element region) in plan view.

The operation of the semiconductor device 10 will now be described.

The semiconductor element 20 includes the passivation layer 70 covering the source electrode layer 40 and the gate electrode layer 60. The source electrode layer 40 includes the source electrode 42 and the source finger 44. The gate electrode layer 60 includes the gate electrode 62 and the gate finger 64. The gate finger 64 at least partially surrounds the source electrode 42. The source finger 44 at least partially surrounds the gate electrode layer 60.

The passivation layer 70 includes the source pad opening 72 exposing the source pad 42A of the source electrode 42. The first conductive member 22 is connected to the source pad 42A. In this structure, the passivation layer 70 receives stress from force applied to the passivation layer 70 from the first conductive member 22, which is in contact with an edge of the source pad opening 72.

The passivation layer 70 includes the source electrode exposure slit 74 partially exposing the source pad peripheral portion 42B. Thus, the source electrode exposure slit 74 reduces the stress applied to the passivation layer 70 from the first conductive member 22, which is connected to the source pad 42A; particularly, stress applied to a portion of the passivation layer 70 located on the source pad peripheral portion 42B. Thus, formation of a passivation crack is limited.

The source electrode exposure slit 74 is annular (closed-annular-shaped). Thus, the stress applied to the passivation layer 70 is reduced effectively along the entire outer circumference of the entire the source pad peripheral portion 42B.

The passivation layer 70 further includes the first and second gate finger exposure slits 78A and 78B partially exposing the gate finger 64 (the first and second gate finger portions 64A and 64B). The first and second gate finger exposure slits 78A and 78B reduce the stress applied to the passivation layer 70 from the first conductive member 22, which is connected to the source pad 42A; particularly, stress applied to a portion of the passivation layer 70 located on the gate finger 64. Thus, formation of a passivation crack is limited.

The first and second gate finger exposure slits 78A and 78B are formed along the entire length of the first and second gate finger portions 64A and 64B. Thus, the stress applied to the passivation layer 70 is reduced effectively along the entire outer circumference of the first and second gate finger portions 64A and 64B.

The passivation layer 70 further includes the source finger exposure slit 79 partially exposing the source finger 44. Thus, the source finger exposure slit 79 reduces the stress applied to the passivation layer 70 from the first conductive member 22, which is connected to the source pad 42A; particularly, stress applied to a portion of the passivation layer 70 located on the source finger 44. Thus, formation of a passivation crack is limited.

The source finger exposure slit 79 is annular (closed-annular-shaped). In other words, the source finger exposure slit 79 is formed along the entire length of the source finger 44. Thus, the stress applied to the passivation layer 70 is reduced effectively along the entire outer circumference of the source finger 44.

The source electrode layer 40 and the gate electrode layer 60 are separated from each other by the separation region 48. The passivation layer 70 is formed in a stepped manner at the separation region 48. Stress is likely to concentrate at a position having such a step. In this regard, the passivation layer 70 includes the source electrode exposure slit 74, the first and second gate finger exposure slits 78A and 78B, and the source finger exposure slit 79 in the vicinity of the separation region 48 at which the steps are formed. This reduces the stress applied to the passivation layer 70, thereby limiting formation of a passivation crack.

The source electrode exposure slit 74, the first and second gate finger exposure slits 78A and 78B, and the source finger exposure slit 79 are arranged to overlap a semiconductor element region that contributes to operation of the semiconductor element 20 in plan view. Thus, formation of a crack in a portion of the passivation layer 70 that overlaps the semiconductor element region in plan view is limited. This increases the reliability of the semiconductor element 20.

The semiconductor device 10 has the advantages described below.
(1-1) The passivation layer 70 includes the source electrode exposure slit 74 partially exposing the source pad peripheral portion 42B (peripheral portion of the source electrode 42). The source electrode exposure slit 74 reduces stress that is applied to the passivation layer 70 from the first conductive member 22, which is connected to the source pad 42A; particularly, stress applied to a portion of the passivation layer 70 located on the source pad peripheral portion 42B. Thus, formation of a passivation crack is limited.
(1-2) The passivation layer 70 further includes the first and second gate finger exposure slits 78A and 78B partially exposing the gate finger 64 (the first and second gate finger portions 64A and 64B). The gate finger 64 is arranged to surround the source electrode 42. Thus, the first and second gate finger exposure slits 78A and 78B further reduce the stress applied to the passivation layer 70 from the first conductive member 22; particularly, stress applied to a portion of the passivation layer 70 located on the gate finger 64. As a result, formation of the source electrode exposure slit 74 and the first and second gate finger exposure slits 78A and 78B further limits formation of a passivation crack.
(1-3) The passivation layer 70 further includes the source finger exposure slit 79 partially exposing the source finger 44. The source finger 44 is arranged to surround the gate finger 64 (the gate electrode layer 60). Thus, the source finger exposure slit 79 further reduces the stress applied to the passivation layer 70 from the first conductive member 22; particularly, stress applied to a portion of the passivation layer 70 located on the source finger 44. As a result, formation of the source electrode exposure slit 74, the first and second gate finger exposure slits 78A and 78B, and the source finger exposure slit 79 further limits formation of a passivation crack.
(1-4) The thickness T2 of the passivation layer 70 is less than the thickness T1 of the source electrode layer 40 and the thickness T1 of the gate electrode layer 60. In other words, the passivation layer 70 is less in thickness than the source electrode layer 40 and the gate electrode layer 60. This limits an increase in the stress produced in the passivation layer 70, thereby limiting formation of a passivation crack.
(1-5) The passivation layer 70 is at least partially arranged in the separation region 48 between the source electrode layer 40 and the gate electrode layer 60 and is formed in a stepped manner at the separation region 48. Thus, the passivation layer 70, which covers the source electrode layer 40 and the gate electrode layer 60, is not flat. When the passivation layer 70 includes a step, stress is likely to concentrate on the passivation layer 70 at the location of the step as compared when the passivation layer 70 is flat. In this regard, the passivation layer 70 includes the source electrode exposure slit 74, the first and second gate finger exposure slits 78A and 78B, and the source finger exposure slit 79 in the vicinity of the separation region 48 at which the steps are formed. This reduces the stress applied to the passivation layer 70, thereby limiting formation of a passivation crack.
(1-6) The passivation layer 70 includes the first covering part 71A covering the upper surface of the source electrode layer 40 and the upper surface of the gate electrode layer 60. The passivation layer 70 further includes the second covering part 71B covering the side surface of the source electrode layer 40 and the side surface of the gate electrode layer 60 at the separation region 48. The first covering part 71A and the second covering part 71B form the steps of the passivation layer 70. The source electrode exposure slit 74, the first and second gate finger exposure slits 78A and 78B, and the source finger exposure slit 79 are formed in the first covering part 71A including the source pad opening 72 (i.e., the upper surface of the passivation layer 70). This reduces the stress applied to the first covering part 71A of the passivation layer 70 from the first conductive member 22, which is connected to the source pad 42A, thereby limiting formation of cracks in the first covering part 71A.
(1-7) The outer shape of the source pad peripheral portion 42B (the source electrode 42) has corners in plan view (generally L-shaped in plan view in FIG. 3). Relative to other portions, stress is more likely to concentrate on portions of the passivation layer 70 corresponding to the corners of the source pad peripheral portion 42B. The source electrode exposure slit 74 reduces the stress applied to the passivation layer 70 on the corners of the source pad peripheral portion 42B, thereby limiting formation of a passivation crack.
(1-8) The source electrode exposure slit 74 is annular. The source electrode exposure slit 74 reduces the stress applied to the passivation layer 70 on the perimeter of the source pad peripheral portion 42B, thereby limiting formation of a passivation crack.
(1-9) The source electrode exposure slit 74 is closed-annular-shaped. The source electrode exposure slit 74 reduces the stress applied to the passivation layer 70 on the entire perimeter of the source pad peripheral portion 42B, thereby limiting formation of a passivation crack.
(1-10) The gate finger 64 (the first and second gate finger portions 64A and 64B) includes corners. Relative to other portions, stress is more likely to concentrate on portions of the passivation layer 70 corresponding to the corners of the gate finger 64. The first and second gate finger exposure slits 78A and 78B reduce the stress applied to the passivation layer 70 on the corners of the gate finger 64, thereby limiting formation of a passivation crack.
(1-11) The gate electrode layer 60 includes the gate electrode 62. The gate finger 64 (the first and second gate finger portions 64A and 64B) extends from the gate electrode 62 so as to annularly surround the source electrode 42. The first and second gate finger exposure slits 78A and 78B extend on the gate finger 64 along the entire length of the gate finger 64 (the first and second gate finger portions 64A and 64B). Thus, the first and second gate finger exposure slits 78A and 78B reduce stress that is applied to the passivation layer 70 along the entire length of the gate finger 64, which annularly surrounds the source electrode 42, thereby limiting formation of a passivation crack.
(1-12) The source finger 44 includes corners. Relative to other portions, stress is more likely to concentrate on portions of the passivation layer 70 corresponding to the corners of the source finger 44. The source finger exposure slit 79 reduces the stress applied to the passivation layer 70 on the corners of the source finger 44, thereby limiting formation of a passivation crack.
(1-13) The source finger exposure slit 79 is annular. The source finger exposure slit 79 reduces stress that is applied to the passivation layer 70 on the source finger 44, thereby limiting formation of a passivation crack.
(1-14) The source finger exposure slit 79 is closed-annular-shaped. The source finger exposure slit 79 reduces stress that is applied to the passivation layer 70 on the entire perimeter of the source finger 44, thereby limiting formation of a passivation crack.
(1-15) The slit width W1 of the source electrode exposure slit 74 is equal to the slit width W2 of the first and second gate finger exposure slits 78A and 78B. More specifically, the source electrode exposure slit 74, which exposes the source pad peripheral portion 42B, has the same width as the first and second gate finger exposure slits 78A and 78B, which expose the gate finger 64. The slit width W1 is also equal to the slit width W3 of the source finger exposure slit 79. More specifically, the source electrode exposure slit 74 has the same width as the source finger exposure slit 79, which exposes the source finger 44. As described above, when the slits formed on the source pad peripheral portion 42B (the source electrode 42) have a minimum width, the functionality of the passivation layer 70 is appropriately maintained.
(1-16) The semiconductor element 20 includes a transistor having a split-gate structure formed in the semiconductor element region (active region). The source electrode exposure slit 74, the first and second gate finger exposure slits 78A and 78B, and the source finger exposure slit 79 are arranged to overlap a semiconductor element region that contributes to operation of the transistor (the semiconductor element 20) in plan view. This appropriately limits formation of a crack in a portion of the passivation layer 70 that overlaps the semiconductor element region in plan view, thereby increasing the reliability of the semiconductor element 20.
(1-17) The first conductive member 22 extends over the gate finger 64 (the first gate finger portion 64A in the example shown in FIG. 3) and the source finger 44 to electrically connect the source pad 42A (the source electrode 42) and the first conductive terminal 14. In this structure, relative to other portions, stress is more likely to be applied to the portion of the gate finger 64 (the first part 64A1 in the example shown in FIG. 3) and the portion of the source finger 44 (the first part 44A in the example shown in FIG. 3) that overlap the first conductive member 22 in plan view. The first gate finger exposure slit 78A and the source finger exposure slit 79 partially expose the corresponding portions of the gate finger 64 and the source finger 44. This reduces the stress applied to the passivation layer 70, thereby limiting formation of a passivation crack.
(1-18) The first conductive member 22 is a bridge-shaped member that is referred to as a clip. The use of the passivation layer 70 according to the present disclosure reduces stress that is applied to the semiconductor device 10 using a clip (e.g., first conductive member 22) on the passivation layer 70.

### MODIFIED EXAMPLES

The embodiment described above may be modified as follows. The embodiment described above and the modified examples described below can be combined as long as the combined modifications remain technically consistent with each other.

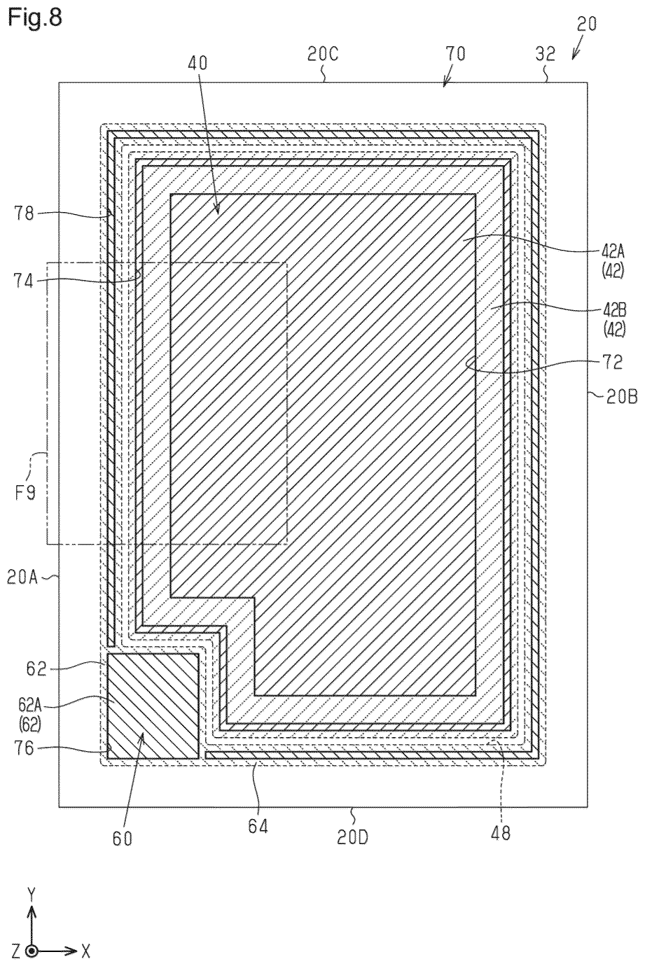

FIG. 8 is a schematic plan view showing an exemplary semiconductor element 20 according to a modified example. As shown in FIG. 8, the source finger 44 (refer to FIGS. 3 and 4) may be omitted from the source electrode layer 40. In this case, the connector 46 is also omitted from the source electrode layer 40. In other words, in FIG. 8, the source electrode layer 40 may include only the source electrode 42 (the source pad 42A and the source pad peripheral portion 42B). In this case, the gate electrode layer 60 may include a gate finger 64 annularly connected to the gate electrode 62 (the gate pad 62A). In this structure, the passivation layer 70 may include a gate finger exposure slit 78 that partially exposes the gate finger 64 along the entire length of the gate finger 64.

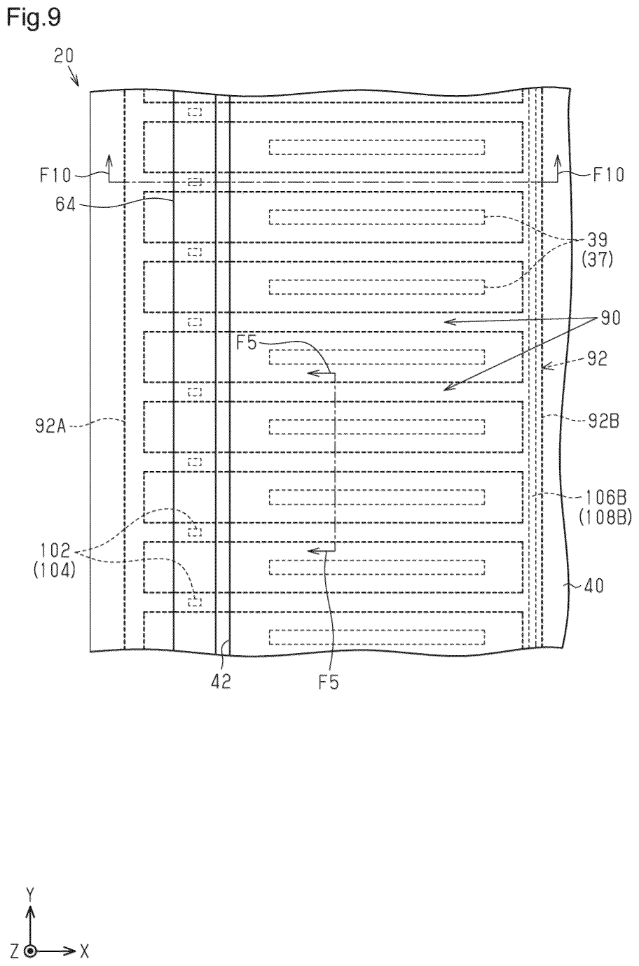

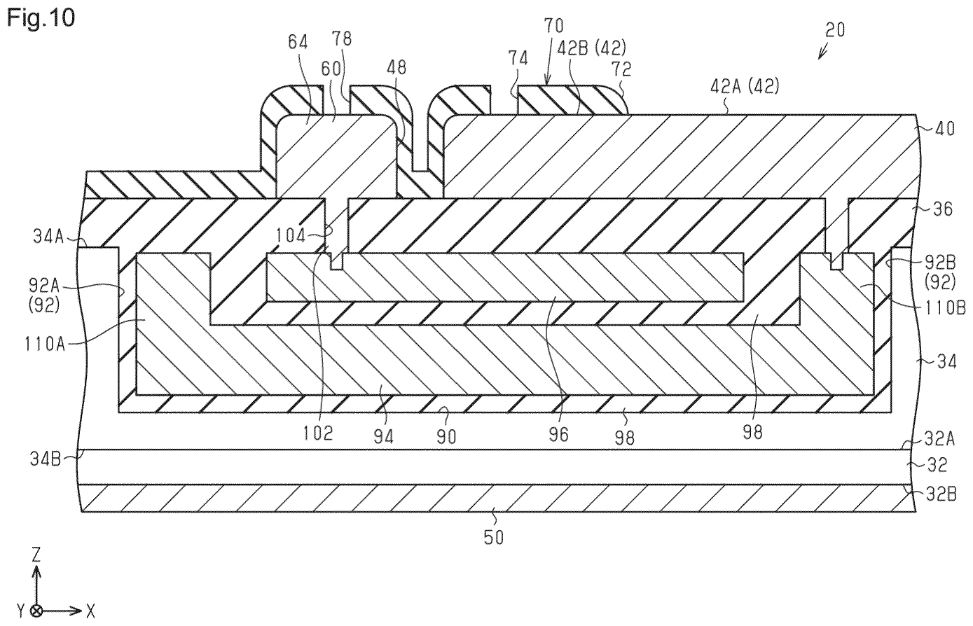

FIG. 9 is a schematic enlarged plan view of a portion of the semiconductor element 20 surrounded by the double-dashed lines F9 shown in FIG. 8. FIG. 10 is a schematic cross-sectional view taken along line F10-F10 shown in FIG. 9. As shown in FIG. 9, in the semiconductor element 20 that does not include the source finger 44 shown in FIG. 8, the first peripheral trench portion 92A does not include the first field plate contact 106A (refer to FIG. 4). The second peripheral trench portion 92B includes the second field plate contact 106B. In this structure, as shown in FIG. 10, the field plate electrode 94 may be connected to the source electrode layer 40 by only the second conductive member 110B. The passivation layer 70 may include the source pad opening 72, the source electrode exposure slit 74, and the gate finger exposure slit 78. The structure of this modified example obtains the same advantages as the embodiment described with reference to FIGS. 3 to 7.

The semiconductor device 10 is not limited to a package having a structure using a lead frame and may have a different package structure.

The semiconductor element 20 is not limited to the transistor described above. The source electrode (the source electrode layer 40) is an example of a first drive electrode. The drain electrode (the drain electrode layer 50) is an example of a second drive electrode. The gate electrode (the gate electrode layer 60) is an example of a control electrode. The semiconductor element 20 may include any transistor that includes the first drive electrode, the second drive electrode, and the control electrode.

The semiconductor element 20 is not limited to a switching element such as a transistor. The structure of the present disclosure is applicable to any semiconductor element that includes a first wiring line, a second wiring line separated from the first wiring line and at least partially surrounding the first wiring line, and a passivation layer that covers the first wiring line and the second wiring line. In this case, in conformance with the structure of the present disclosure, a first slit partially exposing the first wiring line and a second slit partially exposing the second wiring line may be formed so that formation of a passivation crack is limited.

The conductive member used in the structure of the present disclosure is not limited to a clip (bridge-shaped conductive member). In an example, instead of the first conductive member 22, a wire may be used to connect the semiconductor element 20 to the first conductive terminal 14. Also, instead of the second conductive member 24, a wire may be used to connect the semiconductor element 20 to the second conductive terminal 16. As described above, the conductive member may be a wire. When the passivation layer 70 includes a step, a passivation crack may be formed by stress. The passivation layer 70 according to the present disclosure may also be applied to a case in which the conductive member is a wire.

In the embodiment shown in FIGS. 3 to 7, the source finger exposure slit 79, which partially exposes the source finger 44, may be omitted from the passivation layer 70. That is, the passivation layer 70 may completely cover the source finger 44. Even with this structure, the source electrode exposure slit 74, the first gate finger exposure slit 78A, and the second gate finger exposure slit 78B limit cracks in the passivation layer 70.

In the embodiment shown in FIGS. 3 to 7, the first and second gate finger exposure slits 78A and 78B, which partially expose the gate finger 64, may be omitted from the passivation layer 70. That is, the passivation layer 70 may completely cover the gate finger 64. Even with this structure, the source electrode exposure slit 74 and the source finger exposure slit 79 limit cracks in the passivation layer 70.

In the embodiment shown in FIGS. 3 to 7, any one of the first and second gate finger exposure slits 78A and 78B may be omitted.

The source electrode exposure slit 74 is not limited to a closed annular shape and may have an open annular shape. In an example, the source electrode exposure slit 74 may be discontinuous in a portion adjacent to the connector 46 of the source electrode layer 40 or in other portions.

The source electrode exposure slit 74 is not limited to an annular shape. In an example, the source electrode exposure slit 74 may include six slits that are locally formed in portions of the passivation layer 70 corresponding to corners (six corners in the example shown in FIG. 3) of the source pad peripheral portion 42B. In other words, the source electrode exposure slit 74 may expose at least the corners of the peripheral portion of the source electrode 42. In this case, each slit part may be, for example, L-shaped. Relative to other portions, stress is more likely to concentrate on a portion of the passivation layer 70 corresponding to a corner of the peripheral portion of the source electrode 42. Thus, even with the structure of this modified example, formation of a passivation crack may be limited.

The first gate finger exposure slit 78A may be formed in only a portion of the passivation layer 70 corresponding to a corner of the first gate finger portion 64A. In an example, in FIG. 3, the first gate finger exposure slit 78A may locally expose only the portion connecting the first part 64A1 and the second part 64A2 of the first gate finger portion 64A. Relative to other portions, stress is more likely to concentrate on a portion of the passivation layer 70 corresponding to the corner of the first gate finger portion 64A. Thus, even with the structure of this modified example, formation of a passivation crack may be limited.

The second gate finger exposure slit 78B may be formed in only a portion of the passivation layer 70 corresponding to a corner of the second gate finger portion 64B. In an example, in FIG. 3, the second gate finger exposure slit 78B may locally expose only the portion connecting the first part 64B1 and the second part 64B2 of the second gate finger portion 64B. Relative to other portions, stress is more likely to concentrate on a portion of the passivation layer 70 corresponding to the corner of the second gate finger portion 64B. Thus, even with the structure of this modified example, formation of a passivation crack may be limited.

The source finger exposure slit 79 is not limited to a closed annular shape and may have an open annular shape. In an example, the source finger exposure slit 79 may be discontinuous in a portion adjacent to the connector 46 of the source electrode layer 40 or in other portions.

The source finger exposure slit 79 is not limited to an annular shape. In an example, in FIG. 3, the source finger exposure slit 79 may include four slits that are locally formed in portions of the passivation layer 70 corresponding to four corners of the source finger 44. In other words, the source finger exposure slit 79 may expose at least the corners of the source finger 44. In this case, each slit part may be, for example, L-shaped. Relative to other portions, stress is more likely to concentrate on portions of the passivation layer 70 corresponding to the corners of the source finger 44. Thus, even with the structure of this modified example, formation of a passivation crack may be limited.

The source electrode 42 (the outer shape of the source pad peripheral portion 42B) and the source pad 42A are not limited to being generally L-shaped in plan view. The outer shape of the source electrode 42 in plan view may include a corner. Therefore, the first end portion 22F of the first conductive member 22 is not limited to being generally L-shaped in plan view. The outer shape may have a corner in plan view in conformance with the shape of the source pad 42A.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

The directional terms used in the present disclosure such as “vertical,” “horizontal,” “above,” “below,” “top,” “bottom,” “frontward,” “backward,” “lateral,” “left,” “right,” “front,” and “back” will depend upon a particular orientation of the device being described and illustrated. The present disclosure may include various alternative orientations. Therefore, the directional terms should not be narrowly construed.

### CLAUSES

The technical aspects that are understood from the embodiments and the modified examples will be described below. The reference signs of the components in the embodiments are given to the corresponding components in clauses with parentheses. The reference signs are used as examples to facilitate understanding, and the components in each clause are not limited to those components given with the reference signs.

### Clause A1

A semiconductor device (10), including:
a semiconductor element (20); and
a conductive member (22), in which
the semiconductor element (20) includes
   a first wiring line (42) connected to the conductive member (22),
   a second wiring line (60) separated from the first wiring line (42) and at least partially surrounding the first wiring line (42), and
   a passivation layer (70) covering the first wiring line (42) and the second wiring line (60), and
the passivation layer (70) includes
   a first opening (72) partially exposing the first wiring line (42) as a connection region (42A) for the conductive member (22),
   a first slit (74) located between the first opening (72) and the second wiring line (60) and partially exposing the first wiring line (42), and
   a second slit (78; 78A; 78B) partially exposing the second wiring line (60).

### Clause A2

The semiconductor device (10) according to clause A1, in which the passivation layer (70) has a thickness (T2) that is less than a thickness (T1) of the first wiring line (42) and a thickness (T1) of the second wiring line (60).

### Clause A3

The semiconductor device (10) according to clause A1 or A2, in which the passivation layer (70) is at least partially arranged in a separation region (48) located between the first wiring line (42) and the second wiring line (60) and is formed in a stepped manner at the separation region (48).

### Clause A4

The semiconductor device (10) according to clause A3, in which
the first wiring line (42) includes a first surface and a second surface, the second surface of the first wiring line being continuous with the first surface of the first wiring line and defining the separation region (48),
the second wiring line (60) includes a first surface and a second surface, the second surface of the second wiring line being continuous with the first surface of the second wiring line and defining the separation region (48),
the passivation layer (70) includes
   a first covering part (71A) covering the first surface of the first wiring line (42) and the first surface of the second wiring line (60), and
   a second covering part (71B) located in the separation region (48) and covering the second surface of the first wiring line (42) and the second surface of the second wiring line (60),
the passivation layer (70) includes a step formed of the first covering part (71A) and the second covering part (71B), and
the first opening (72), the first slit (74), and the second slit (78A; 78B) are formed in the first covering part (71A).

### Clause A5

The semiconductor device (10) according to any one of clauses A1 to A4, in which the first wiring line (42) includes
a source pad (42A) exposed as the connection region from the first opening (72), and
a source pad peripheral portion (42B) located around the source pad (42A) and forming a peripheral portion of the first wiring line (42), and the first slit (74) is located on the source pad peripheral portion (42B).

### Clause A6

The semiconductor device (10) according to clause A5, in which
in plan view, the source pad peripheral portion (42B) has an outer shape including a corner, and
the first slit (74) is located on the corner of the source pad peripheral portion (42B).

### Clause A7

The semiconductor device (10) according to any one of clauses A1 to A6, in which the first slit (74) is annular.

### Clause A8

The semiconductor device (10) according to clause A7, in which the first slit (74) is closed-annular-shaped.

### Clause A9

The semiconductor device (10) according to any one of clauses A1 to A8, in which
the second wiring line (60) includes a gate finger (64) separated from the first wiring line (42) and extending along the first wiring line (42), and
the second slit (78A; 78B) is located on the gate finger (64).

### Clause A10

The semiconductor device (10) according to clause A9, in which
the gate finger (64) includes a corner, and
the second slit (78A; 78B) is located on the corner of the gate finger (64).

### Clause A11

The semiconductor device (10) according to clause A9 or A10, in which
the second wiring line (60) further includes a gate electrode (62),
the gate finger (64) extends from the gate electrode (62) so as to annularly surround the first wiring line (42), and
the second slit (78A; 78B) is located on the gate finger (64) along an entire length of the gate finger (64).

### Clause A12

The semiconductor device (10) according to any one of clauses A1 to A11, in which
the semiconductor element (20) further includes a third wiring line (44) separated from the second wiring line (60) and at least partially surrounding the second wiring line (60),
the passivation layer (70) further covers the third wiring line (44), and
the passivation layer (70) further includes a third slit (79) partially exposing the third wiring line (44).

### Clause A13

The semiconductor device (10) according to clause A12, in which
the third wiring line (44) includes a source finger (44) separated from the second wiring line (60) and extending along the second wiring line (42), and
the third slit (79) is located on the source finger (44).

### Clause A14

The semiconductor device (10) according to clause A13, in which
the source finger (44) includes a corner, and
the third slit (79) is located on the corner of the source finger (44).

### Clause A15

The semiconductor device (10) according to clause A13 or A14, in which
the source finger (44) annularly surrounds the second wiring line (60), and
the third slit (79) is annular.

### Clause A16

The semiconductor device (10) according to clause A15, in which the third slit (79) is closed-annular-shaped.

### Clause A17

The semiconductor device (10) according to any one of clauses A1 to A16, in which the first slit has a width (W1) that is equal to a width of the second slit (W2).

### Clause A18

The semiconductor device (10) according to any one of clauses A1 to A17, in which
the semiconductor element (20) includes a transistor having a split-gate structure formed in a semiconductor element region, and
in plan view, the first slit (74) and the second slit (78A; 78B) overlap the semiconductor element region.

### Clause A19

The semiconductor device (10) according to any one of clauses A1 to A18, further including:
a conductive terminal (14) located adjacent to the semiconductor element (20), in which
the conductive member (22) extends over the second wiring line (60) and connects the first wiring line (42) and the conductive terminal (14), and
the second slit (78A; 78B) exposes a portion of the second wiring line (60) that overlaps the conductive member (22) in plan view.

### Clause A20

The semiconductor device (10) according to any one of clauses A1 to A19, in which the conductive member (22) includes a bridge-shaped clip including a flat first end portion, a flat second end portion, and an intermediate portion located between the first end portion and the second end portion, the intermediate portion being bent in a stepped manner.

### Clause B1

A semiconductor device (10), including:
a semiconductor element (20); and
a conductive member (22), in which
the semiconductor element (20) includes
   a first wiring line (42) connected to the conductive member (22),
   a second wiring line (60) separated from the first wiring line (42) and at least partially surrounding the first wiring line (42),
   a third wiring line (44) separated from the second wiring line (60) and at least partially surrounding the second wiring line (60), and
   a passivation layer (70) covering the first wiring line (42), the second wiring line (60), and the third wiring line (44),
the passivation layer (70) includes
   a first opening (72) partially exposing the first wiring line (42) as a connection region (42A) for the conductive member (22),
   an inner slit (74) located between the first opening (72) and the second wiring line (60) and partially exposing the first wiring line (42), and
   at least one outer slit (78; 78A; 78B; 79) exposing at least one of a portion of the second wiring line (60) and a portion of the third wiring line (44).

### Clause C1

A semiconductor element (20), including:
a first wiring line (42);
a second wiring line (60) separated from the first wiring line (42) and at least partially surrounding the first wiring line (42); and
a passivation layer (70) covering the first wiring line (42) and the second wiring line (60),
the passivation layer (70) includes
   a first opening (72) partially exposing the first wiring line (42),
   a first slit (74) located between the first opening (72) and the second wiring line (60) and partially exposing the first wiring line (42), and
   a second slit (78; 78A; 78B) partially exposing the second wiring line (60).

The description above illustrates examples. One skilled in the art may recognize further possible combinations and replacements of the components and methods (manufacturing processes) in addition to those listed for purposes of describing the techniques of the present disclosure. The present disclosure is intended to include any substitute, modification, changes included in the scope of the disclosure including the claims.

1. A semiconductor device, comprising:
a semiconductor element; and
a conductive member, wherein
the semiconductor element includes
a first wiring line connected to the conductive member,
a second wiring line separated from the first wiring line and at least partially surrounding the first wiring line, and
a passivation layer covering the first wiring line and the second wiring line, and
the passivation layer includes
a first opening partially exposing the first wiring line as a connection region for the conductive member,
a first slit located between the first opening and the second wiring line and partially exposing the first wiring line, and
a second slit partially exposing the second wiring line.

2. The semiconductor device according to claim 1, wherein the passivation layer has a thickness that is less than a thickness of the first wiring line and a thickness of the second wiring line.

3. The semiconductor device according to claim 1, wherein the passivation layer is at least partially arranged in a separation region located between the first wiring line and the second wiring line and is formed in a stepped manner at the separation region.

4. The semiconductor device according to claim 3, wherein
the first wiring line includes a first surface and a second surface, the second surface of the first wiring line being continuous with the first surface of the first wiring line and defining the separation region,
the second wiring line includes a first surface and a second surface, the second surface of the second wiring line being continuous with the first surface of the second wiring line and defining the separation region,
the passivation layer includes
a first covering part covering the first surface of the first wiring line and the first surface of the second wiring line, and
a second covering part located in the separation region and covering the second surface of the first wiring line and the second surface of the second wiring line,
the passivation layer includes a step formed of the first covering part and the second covering part, and
the first opening, the first slit, and the second slit are formed in the first covering part.

5. The semiconductor device according to claim 1, wherein
the first wiring line includes
a source pad exposed as the connection region from the first opening, and
a source pad peripheral portion located around the source pad and forming a peripheral portion of the first wiring line, and
the first slit is located on the source pad peripheral portion.

6. The semiconductor device according to claim 5, wherein
in plan view, the source pad peripheral portion has an outer shape including a corner, and
the first slit is located on the corner of the source pad peripheral portion.

7. The semiconductor device according to claim 1, wherein the first slit is annular.

8. The semiconductor device according to claim 7, wherein the first slit is closed-annular-shaped.

9. The semiconductor device according to claim 1, wherein
the second wiring line includes a gate finger separated from the first wiring line and extending along the first wiring line, and
the second slit is located on the gate finger.

10. The semiconductor device according to claim 9, wherein
the gate finger includes a corner, and
the second slit is located on the corner of the gate finger.

11. The semiconductor device according to claim 9, wherein
the second wiring line further includes a gate electrode,
the gate finger extends from the gate electrode so as to annularly surround the first wiring line, and
the second slit is located on the gate finger along an entire length of the gate finger.

12. The semiconductor device according to claim 1, wherein
the semiconductor element further includes a third wiring line separated from the second wiring line and at least partially surrounding the second wiring line,
the passivation layer further covers the third wiring line, and
the passivation layer further includes a third slit partially exposing the third wiring line.

13. The semiconductor device according to claim 12, wherein
the third wiring line includes a source finger separated from the second wiring line and extending along the second wiring line, and
the third slit is located on the source finger.

14. The semiconductor device according to claim 13, wherein
the source finger includes a corner, and
the third slit is located on the corner of the source finger.

15. The semiconductor device according to claim 13, wherein
the source finger annularly surrounds the second wiring line, and
the third slit is annular.

16. The semiconductor device according to claim 15, wherein the third slit is closed-annular-shaped.

17. The semiconductor device according to claim 1, wherein the first slit has a width that is equal to a width of the second slit.

18. The semiconductor device according to claim 1, wherein
the semiconductor element includes a transistor having a split-gate structure formed in a semiconductor element region, and
in plan view, the first slit and the second slit overlap the semiconductor element region.

19. The semiconductor device according to claim 1, further comprising:
a conductive terminal located adjacent to the semiconductor element, wherein
the conductive member extends over the second wiring line and connects the first wiring line and the conductive terminal, and
the second slit exposes a portion of the second wiring line that overlaps the conductive member in plan view.

20. The semiconductor device according to claim 1, wherein the conductive member includes a bridge-shaped clip including a flat first end portion, a flat second end portion, and an intermediate portion located between the first end portion and the second end portion, the intermediate portion being bent in a stepped manner.
